(19) United States
(12) Patent Application Publication
(10) Pub. No.: US 2009/0294105 A1
(43) Pub. Date: Dec. 3, 2009

(54) Selectively Grooved Cold Plate for Electronics Cooling

(75) Inventors: Nagapatnam Sundararajan, Hyderabad (IN); Konala Lakshmana Reddy, Hyderabad (IN); Upperla Narasimha Rao, Hyderabad (IN); Shanmugan Veeramani, Hyderabad (IN)

Correspondence Address: THE WEBB LAW FIRM, P.C., 700 KOPPERS BUILDING, 436 SEVENTH AVENUE, PITTSBURGH, PA, 15219, US

(73) Assignee: BHARAT HEAVY ELECTRICALS LIMITED, New Delhi (IN)

(21) Appl. No.: 11/886,604

(22) PCT Filed: Aug. 10, 2005
(86) PCT No.: PCT/IN2005/000267

§ 371 Date: Jul. 1, 2009

(30) Foreign Application Priority Data
Mar. 22, 2005 (IN) 199/KOL/05

(51) Int. Cl. H05K 7/20; F28D 15/00; F28F 7/00; F28F 3/12

(52) U.S. Cl. 165/104.33; 165/104.19; 165/185

(57) ABSTRACT

An improved heat exchange device adaptable for cooling electronic components mounted over at least one external surface of the device, comprising a base plate; a cover plate; a clad plate interposed between the base plate and the cover plate, the base plate and the cover plate, with the clad sheet being rigidly jointed to form a single integrated plate; at least one inlet port and at least one outlet port atone end and/or at the opposite ends of the formed plate for entry and exit of a cooling medium, wherein the base plate is configured to have a plurality of flow-passages each comprising several machined grooves having varied dimensions predetermined in registration with respective thermal footprint of the electronic components thereby optimizing the heat transfer rate, and in that a plurality of interconnections being designed between the grooves constituting one of a series and parallel flow-paths.

### FIELD OF INVENTION

The invention relates to an improved heat exchanger device adaptable for cooling the electronic components mounted over the device. The electronic components dissipate varied thermal loads which depend upon the shape, size and function of the electronic components. A fluid passing through a plurality of in-built passages within the device extracts the heat generated by the electronic components by convection and transfers the same to an adjacently disposed sink.

### BACKGROUND ART

The Commercially available heat exchangers for cooling of power electronics and other high watt density electronics applications generally are manufactured by pressing 0.25″ copper tubing into a channeled aluminum. Such devices are available in six and twelve inch long configurations having straight and beaded fittings. The tap holes can be drilled according to customer requirements.

Another design of commercially available. devices constitute a high performance series of Cold Plates. It provides low thermal resistance and dual-sided component mounting, with the capability of being drilled and tapped on one surface. This all-aluminum device is manufactured utilizing vacuum brazing techniques commonly found in custom cold plates. To build these cold plates, high-performance corrugated aluminum fin is brazed into the liquid cavity below the mounting surfaces.

U.S. Pat. No. 6,367,543 BI describes a liquid cooled heat sink. This sink is having a cooling housing including a peripheral side wall extending from the perimeter of a bottom wall and a lid sized to engage the peripheral side wall so as to form a chamber. A fluid inlet port and a fluid outlet port are defined through the lid, and disposed in fluid communication with the chamber.

Another version of liquid cooled heat sink has been patented vide U.S. Pat. No. 6,397,932 BI and U.S. Pat. No. 6,719,039 B2. In these versions a plurality of pins project outwardly from the bottom wall so as to be positioned within the chamber and arranged in a staggered pattern. The pins include an end that engages the undersurface of the lid. A third version of liquid cooled heat sink has been patented vide U.S. Pat. No. 6,578,626 BI. In this embodiment, a corrugated fin having a plurality of corrugations is positioned within the chamber so that at least one of the corrugations engages the bottom wall and at least one of the corrugations engages the under surface of the lid.

The U.S. Pat. No. 6,819,561 B2 describes a heat exchange system equivalent to that of the device described hereinabove. Such a device achieves heat removal from high-power, heat-producing electronic components by conduction and convection. The heat exchange system comprises a metal tube that has been forged and drawn so as to define a flow channel for a cooling fluid, wherein the tube has an inner surface that includes a plurality of integral which that are structured and arranged to increase the available surface area of the inner surface of the metal tube exposed to the fluid and further has an outer surface that is in direct communication with the heat producing electronics components. Coolant fluids are circulated through the flow channel, preferably, at turbulent flow conditions to minimize thermal resistance. The invention further provides a self-cooling self-supporting electronic device which comprises one or more high-power electronic components, the heat exchange means, and an attaching system for attaching high-power electronic components to the heat exchange system.

U.S. Pat. No. 5,924,481 describes another type of cooling device for electronic components. A header tank for accommodating refrigerant is formed on one side of the device, on the other side of which at least one electronic component is mounted. A plurality of loop pipes in which the refrigerant is circulated are connected with the header tank. The plurality of loop pipes are arranged substantially parallel with the device. The radiating area of the loop pipes disposed at a distal end of the device is larger than the radiating area of the loop pipes configured at the proximal end.

U.S. Pat. No. 6,634,421, describes a high performance cold plate for electronic cooling. Here a fluid cooling device and a method for manufacturing the fluid cooling device are disclosed. The fluid cooling device includes a plurality of cold plate members, each having a plurality of imperforate plate portions and several perforate portions arranged in line; and at least one connector for connecting the plate portions together at one end thereof. The cold plate numbers are arranged in a stack, wherein respective plate portions of each Cold Plates members are configured in registration with perforate portions formed in the immediately adjacent cold plate members in the stack. The fluid cooling device provides very high heat transfer by close clearance laminar developing flow, thereby increasing the thermal performance of the fluid cooling device while maintaining low pressure drop. The method for manufacturing of the fluid cooling device includes producing a plurality of cold plate members from a planner metal type, or thin layer stock; positioning the cold plate members relative to each other so that the respective imperforate plate portions of each cold plate member are disposed in registration with the perforate portions formed in the immediately adjacent cold plate members; and joining each cold plate member with the immediately adjacent cold plate members.

The prior art devices described hereinabove have the flow paths designed either using coiled tubes or plate fins sandwiched in between at least two flats plates. Another design of prior art device has a plurality of pins projected outwardly from the bottom wall so as to be positioned within the bottom and top plates appropriate side walls and inlet outlet connectors. In yet another variant of the prior art the plurality of pins are replaced by several fins having a plurality of corrugations, keeping other components unaltered. All the above designs address the problem of heat generation in electronic devices by heat removal on an uniform basis throughout the plate surfaces. In practice, heat emission by all the electronic components mounted on a heat exchanger device will not be uniform and also the same electronic component can have different heat release rates at different locations. Hence, a solution for uniform removal of heat throughout the plate results in comparatively higher device temperatures and higher pumping power requirement for circulation of cooling fluid.

An object of this invention is to provide an improved heat exchanger device which eliminates the disadvantages of the prior art devices.

Another object of the invention is to provide an improved heat exchanger device which improves the heat transfer rate of cooling fluid.

Yet another object of the invention is to provide an improved heat exchanger device which comprises flow-passages to improve flow-velocity of the cooling medium there through.

Still another object of the invention is to provide an improved heat exchanger device which requires bonding of the base plate and the top plate eliminating thereby additional bonding of the flow-passages.

Still yet another object of the invention is to provide an improved heat exchanger device which is easy to manufacture, cost-effective and designed to have in-built machine grooved flow-passages in registration with disposition of electronic components having varied heat transfer rate thereby achieving improved cooling effect.

### SUMMARY OF THE INVENTION

Accordingly there is provided an improved heat exchanger device adaptable for cooling electronic components mounted over at least one external surface of the device, comprising a base plate; a cover plate; a clad sheet interposed between the base plate and the cover plate, the base plate and the cover plate with the clad sheet being rigidly jointed to form a single integrated plate; at least one inlet port and at least one outlet port at one end and/or at the opposite ends of the formed plate for entry and exit of a cooling medium, characterized in that the base plate is configured to have a plurality of flow-passages each comprising several machined grooves having varied dimensions predetermined in registration with respective thermal footprint of the electronic components thereby optimizing the heat transfer rate, and in that a plurality of interconnections being designed between the grooves constituting one of a series and parallel flow-paths.

### BRIEF DESCRIPTION OF THE ACCOMPANYING DRAWINGS

FIG. 1 shows the base plate component with machined grooves of the improved heat exchanger device of the invention

FIG. 2 shows the pre assembled view of the improved heat exchanger device according to the embodiment of the present design

FIG. 3 shows a table reflecting the performance test of heat exchanger device

FIG. 4 shows a temperature effectiveness chart of the heat exchanger device.

FIG. 5 shows a performance factor of the heat exchanger device.

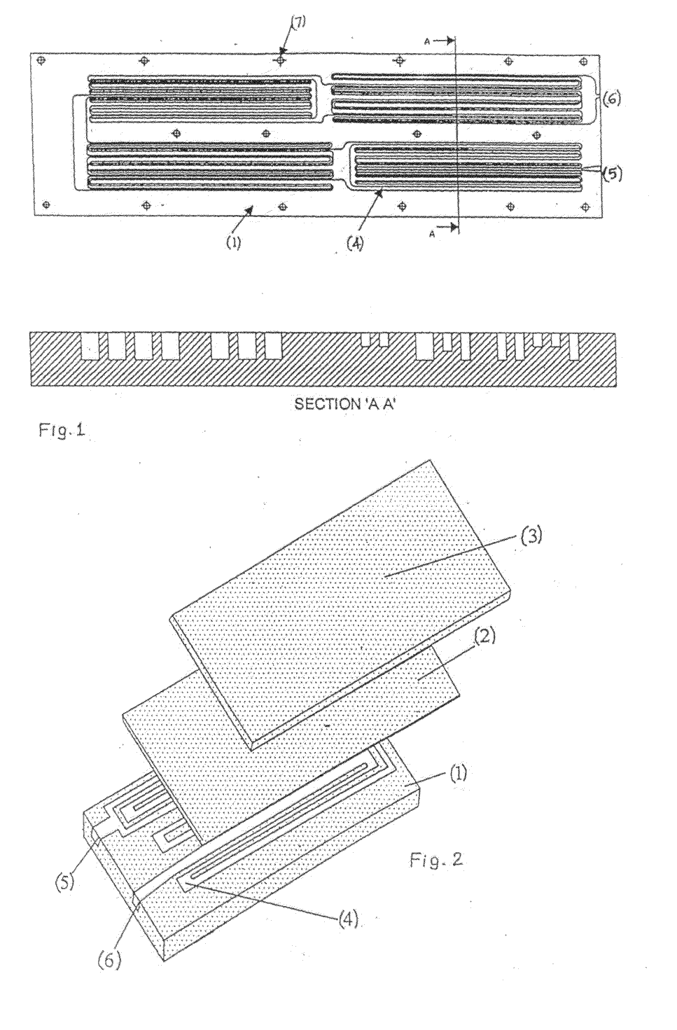

### DETAIL DESCRIPTION OF A PREFERRED EMBODIMENT OF THE INVENTION

An improved heat exchanger device basically constitutes a cold plate adaptable to cool the electronic components mounted on the surface of the Plate. As the heat generated by any electronic component is not uniform through out its body, in practice there would be certain areas of high heat flux zones and the remaining areas would constitute low heat flux zones. In one aspect of the present invention the fluid flow passages are designed such that higher fluid velocities and higher heat transfer surface are provided underneath the high heat flux zones of the electronic components and low fluid velocities underneath the low heat flux zones. The main variables considered in designing the flow path configuration are:
Length of the passage
Width of the passage
Depth of the passage
Number of parallel flow paths.

The cooling of a typical electronic component having a high heat zone of 3 inches by 5 inches size which emits about one KW heat and a low heat zone of 2 inches by 13 inches size which generates about 0.2 KW heat is considered. The design has been evolved considering use of two each of such electronic components mounted on a single Cold Plate of an improved heat exchanger device. The overall size of the Cold Plate is 500 to 700 mm by 250 to 350 mm.

The improved heat exchanger device has essentially three major components, a base plate (1) where the fluid passages (4) are configured, a clad sheet (2) to effect the vacuum brazing and a cover plate (3). The base plate (1) is of 8 to 16 mm thick, the clad sheet (2) is about 0.3 to 0.8 mm thick and the cover plate (3) is of 2 to 4 mm thick. The fluid passages comprise a plurality of grooves configured on the base plate (1) preferably by using a Numerically Controlled (NC) machine. The flow passages (4) have varied depth from 5 mm to 10 mm; with varied width from 3 mm to 8 mm. The width of the solid portions between two adjacent passages (4) varies between 2 mm to 11 mm. The contour of the flow passages (4) comprise a plurality of U-bends. The high heat flux zones have only two parallel paths with long path having longer path length. Such restricting of the number of parallel paths will increase the fluid velocity, and the resultant increase in turbulence will enhance the heat transfer rate. The low heat flux zones are provided with parallel paths and larger cross-sectional areas which ensure low fluid velocities so that fluid pressure drop can be minimized. As per the mounting requirement of electronic components, suitable number of landings (solid areas) are provided in between the flow passages (4). At least one inlet and one outlet nozzle is provided for fluid entry and exit (not shown).

The bottom plate (1) is covered with the top plate (3) keeping the clad plate (2) in between. They are brazed together using a vacuum brazing furnace. The vacuum brazing process is an established process for aluminum materials.

In one embodiment of the invention the flow passages have equal cross section but having at least one serial path for high heat flux zone and multiple parallel paths for low heat flux zones. In an alternative embodiment at least one inlet and one outlet port (5,6) are arranged in the vertical direction by having a grooved rectangular chamber at the inlet and outlet (5,6). Preferably a hole can be drilled on the outer surface to connect the fluid flow path with external connectors (not shown).

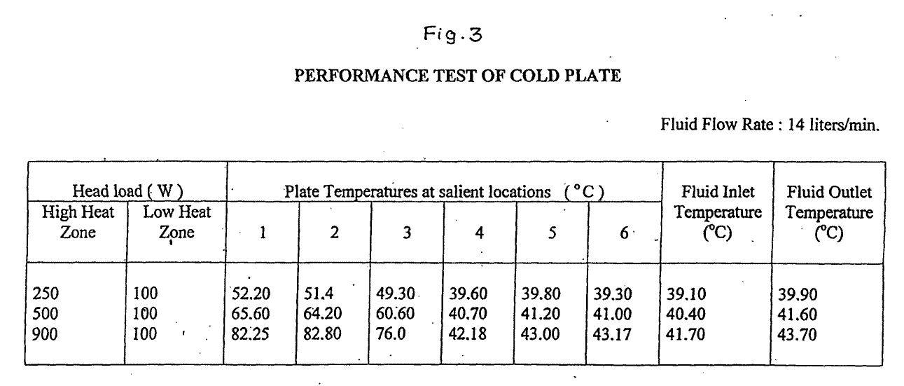

A typical device manufactured according to the invention and considering the selected parameters has been tested with a fluid flow rate of 14 liters per minute. Electronic components are mounted and the temperature profile has been evaluated. Typical test results are given in FIG. 3.

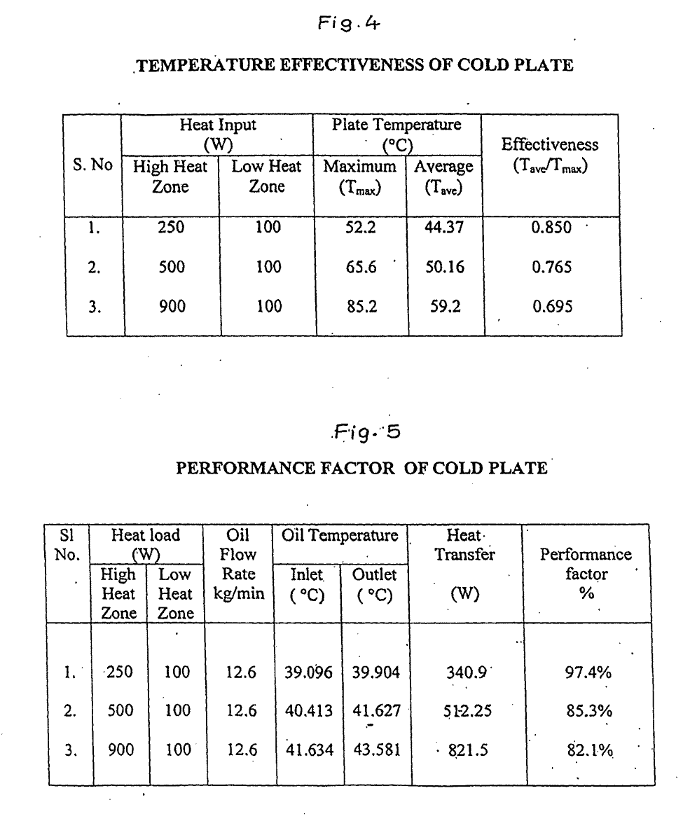

A test has been conducted to evaluate the Temperature Effectiveness of the device for different loads. Temperature effectiveness is defined as the ratio of the average to the maximum device temperature. It is an indicator which shows how effectively the device is designed to extract the heat from high heat flux zones. The average plate temperature is calculated as an arithmetic average of all the plate temperatures recorded. Temperature Effectiveness is high at lower heat loads and decreases as the load is increased. The results are shown in FIG. 4.

Another test was conducted to evaluate the Performance Factor. The Performance Factor is defined as the ratio of heat picked up by the fluid to the total heat input into the plate and the result is expressed in percentage. FIG. 5 shows the Performance Factor of the device. At lower loads the Performance Factor is as high as 97.4 percent and it decreases as heat load increases.

It is to be understood that the present invention is by no means limited only to the particular constructions herein disclosed and shown in the drawings, but also includes any modifications or equivalents within the scope of the claims.

1-9. (canceled)

10. A heat exchanger device for cooling electronic components mounted over at least one external surface of the device, comprising
a base plate;
a cover plate;
a clad sheet interposed between the base plate and the cover plate, the clad sheet being rigidly jointed to form a single integrated plate;
at least one inlet port and at least one outlet port at one end and/or at the opposite ends of the integrated plate for entry and exit of a cooling medium,
wherein the base plate is configured to have a plurality of flow passages comprising at least one high heat flux zone having only two parallel paths with dissimilar lengths, and at least one low heat flux zone having parallel paths with larger cross sectional area,
the flow passages comprise a plurality of grooves with a plurality of U-bends and landings, the grooves having varied depths and widths, and
a width of the landings between two adjacent flow passages is different than a width of the flow passages.

11. The device as claimed in claim 10, wherein the thickness of the base plate, the clad sheet, and the cover plate is 8 to 16 mm, 0.3 to 0.8 mm and 2 to 4 mm, respectively.

12. The device as claimed in claim 10, wherein the depth and the width of the flow passages varies between 5 mm to 10 mm and 3 mm to 8 mm, respectively.

13. The device as claimed in claim 10, wherein the width of the landings between two adjacent flow passages varies between 2 mm to 11 mm.

14. The device as claimed in claim 10, wherein the grooves constitute machined grooves configured by a precision milling machine.

15. The device as claimed in claim 10, wherein the plurality of flow-passages are provided on the base plate such that the electronic components are accommodated in a plurality of mounting holes provided in several intermittent landings of the base plate.

16. The device as claimed in claim 10, wherein the interconnections between the grooves comprise one of a parallel and series flow path.

17. The device as claimed in claim 10, wherein the cooling fluid is air, vapour, oil, water glycol mixture, silicone based liquids, fluorocarbon or any combination thereof.

18. The device as claimed in claim 10, wherein the base plate and the cover plate comprise metallic material, the metallic material being aluminium, aluminium alloy, copper, copper alloy, steel or any combination thereof.

19. The device as claimed in claim 14, wherein the precision milling machine is a numerically controlled machine.
